(19) United States
(12) Patent Application Publication
(10) Pub. No.: US 2023/0215771 A1
(43) Pub. Date: Jul. 6, 2023

(54) ELECTRONIC DEVICE

(71) Applicant: InnoLux Corporation, Miao-Li County (TW)

(72) Inventors: Chien-Chih LIAO, Miao-Li County (TW); Kuei-Sheng CHANG, Miao-Li County (TW); Hsing-Yuan HSU, Miao-Li County (TW); Po-Yang CHEN, Miao-Li County (TW); I-An YAO, Miao-Li County (TW)

(73) Assignee: InnoLux Corporation, Miao-Li County (TW)

(21) Appl. No.: 17/993,999

(22) Filed: Nov. 25, 2022

(30) Foreign Application Priority Data
Dec. 30, 2021 (CN) 202111649720.7

(51) Int. Cl. H01L 21/66

(52) U.S. Cl. CPC H01L 22/32; G06V 40/13

(57) ABSTRACT

An electronic device includes a substrate, a plurality of first pads, a plurality of sensing units and a plurality of test pads. The first pads are disposed on the substrate, the sensing units are disposed on the substrate and electrically connected to the first pads, and the test pads are disposed on the substrate and electrically connected to the sensing units.

### BACKGROUND OF THE DISCLOSURE

### 1. Field of the Disclosure

The present disclosure relates to an electronic device, and more particularly to an electronic device including sensing units and display units.

### 2. Description of the Prior Art

With the technical developments of electronic devices, sensors with fingerprint identification function or other types of sensors are integrated into various electronic devices and widely used. Users can directly manage electronic devices through fingerprint identification. Additionally, fingerprints can be quickly identified and are difficult to forge; therefore, fingerprint identification technology can provide convenience and security. In recent years, industries have been dedicated to integrating fingerprint identification functions and display functions into the same electronic device while simultaneously improving the qualification rate of electronic devices.

### SUMMARY OF THE DISCLOSURE

An embodiment of the present disclosure provides an electronic device, which includes a substrate, a plurality of first pads, a plurality of sensing units and a plurality of test pads. The first pads are disposed on the substrate, the sensing units are disposed on the substrate and electrically connected to the first pads, and the test pads are disposed on the substrate and electrically connected to the sensing units.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of an electronic device according to a first embodiment of the present disclosure.

FIG. 2 is a schematic diagram of a sensing unit and display units according to the first embodiment of the present disclosure.

FIG. 3 is a partially enlarged schematic diagram of the electronic device according to the first embodiment of the present disclosure.

FIG. 4 is a partially enlarged schematic diagram of an electronic device according to a second embodiment of the present disclosure.

FIG. 5 is a schematic diagram of an electronic device according to a third embodiment of the present disclosure.

FIG. 6 is a partially enlarged schematic diagram of the electronic device according to the third embodiment of the present disclosure.

FIG. 7 is a partially enlarged schematic diagram of an electronic device according to a fourth embodiment of the present disclosure.

FIG. 8 is a schematic diagram of an electronic device according to a fifth embodiment of the present disclosure.

FIG. 9 is a partially enlarged schematic diagram of the electronic device according to the fifth embodiment of the present disclosure.

FIG. 10 is a schematic diagram of an electronic device according to a sixth embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams of electronic devices or a portion of the electronic devices, and components therein may not be drawn to scale. The numbers and dimensions of the components in the drawings are just illustrative, and are not intended to limit the scope of the present disclosure.

Certain terms are used throughout the specification and the appended claims of the present disclosure to refer to specific components. Those skilled in the art should understand that electronic equipment manufacturers may refer to a component by different names, and this disclosure does not intend to distinguish between components that differ in name but not function. In the following description and claims, the terms “comprise”, “include” and “have” are used in an open-ended fashion, so they should be interpreted as “including but not limited to . . . ”.

Directional terms such as “up”, “down”, “front”, “back”, “left” and “right” used in the present disclosure are only directions with reference to the drawings. Therefore, the directional terms are used for illustration, and are not intended to limit the scope of the present disclosure. In the drawings, each drawing illustrates the general features of methods, structures and/or materials used in specific embodiments. However, these drawings should not be interpreted as defining or limiting the scope or characteristics of these embodiments. For example, the relative size, thickness and position of each layer, region and/or structure may be shrunk or enlarged for clarity.

It should be understood that when a component or layer is referred to as being “on” or “disposed on” another component or layer, or “connected to” another component or layer, it may be directly on the another component or layer or directly connected to the another component or layer, or there may be an interposed component or layer between the two components or layers (indirect case). Conversely, when a component is referred to as being “directly on” another component or layer, “directly disposed on” another component or layer, or “directly connected to” another component or layer, there are no interposed components or layers between the two components or layers. In addition, the arrangement relationship between different components may be explained by the content of the drawings.

An electrical connection may be a direct connection or an indirect connection. When two elements are electrically connected, the electrical signals may be transmitted by direct contact, and there are no other elements presented between the two elements. When two elements are electrically connected, the electrical signals may be transmitted through the intermediate element bridging the two elements. When it is mentioned “one element is directly electrically connected to another element”, it means that the element is directly electrically connected to another element without other elements presented between the two elements.

Terms “equal” or “the same” usually mean within 20% of a given value, or within 10%, 5%, 3%, 2%, 1% or 0.5% of the given value.

Terms “first”, “second”, “third”, etc. may be used herein to describe various components, these components should not be limited by these terms. These terms may be used to distinguish different components in the specification. The same terms may not be used in the claims, and the components in the claims may be described by the terms “first”, “second”, “third”, etc. according to the order of the components presented in the claims. Thus, a first component discussed below may be termed as a second component in the claims without departing from the present disclosure.

It should be understood that according to the following embodiments, features of different embodiments may be replaced, recombined or mixed to constitute other embodiments without departing from the spirit of the present disclosure.

The electronic device of the present disclosure may include a display device, a backlight device, an antenna device, a sensing device or a tiled device, but not limited thereto. The electronic devices may be bendable, flexible or rollable electronic devices. The display device may include a non-self-luminous display device or a self-luminous display device, but not limited thereto. The antenna device may be a liquid crystal type antenna device or a non-liquid crystal type antenna device, and the sensing device may be a sensing device capable of sensing capacitance, light, thermal energy or ultrasonic waves, but not limited thereto.

Electronic components may include passive components and active components, such as capacitors, resistors, inductors, diodes, transistors, etc. The diodes may include light emitting diodes or photodiodes, but not limited thereto. The electronic device may include liquid crystal molecules, light emitting diodes (LED), quantum dot (QD) material, fluorescence material, phosphor, other suitable materials, or any combination thereof, but not limited thereto. The light emitting diode may include, for example, an organic light emitting diode (OLED), a mini light emitting diode (mini-LED), a micro light emitting diode (micro-LED) or quantum dots (QDs) light emitting diode (such as QLED, QDLED), other suitable light emitting diodes, or any combination thereof, but not limited thereto. The tiled device may include, for example, a tiled display device or a tiled antenna device, but not limited thereto. It should be noted that the electronic device can be any combination of the above devices, but not limited thereto.

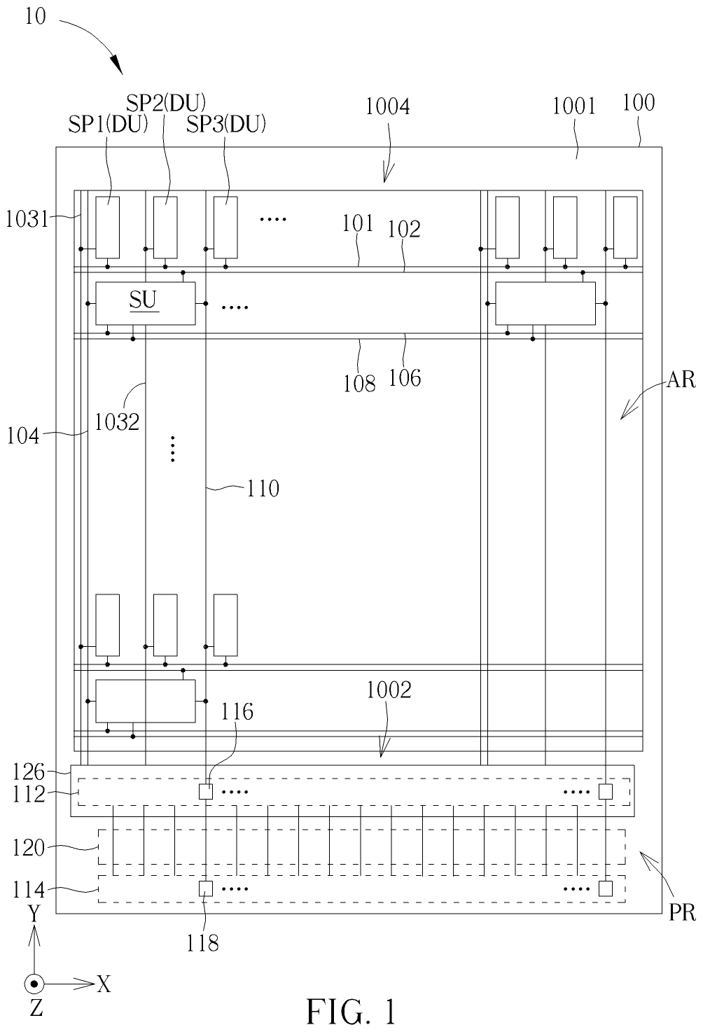

A direction X, a direction Y and a direction Z are shown in the following drawings. The direction Z may be a normal direction or a top view direction. As shown in FIG. 1, the direction Z may be perpendicular to a top surface 1001 of a substrate 100. The direction X and the direction Y may be horizontal directions and may be perpendicular to the direction Z. As shown in FIG. 1, the direction X and the direction Y may be parallel to the top surface 1001 of the substrate 100, and the direction X may be perpendicular to the direction Y. The spatial relationship of the structure may be explained according to the direction X, the direction Y and the direction Z in the following drawings.

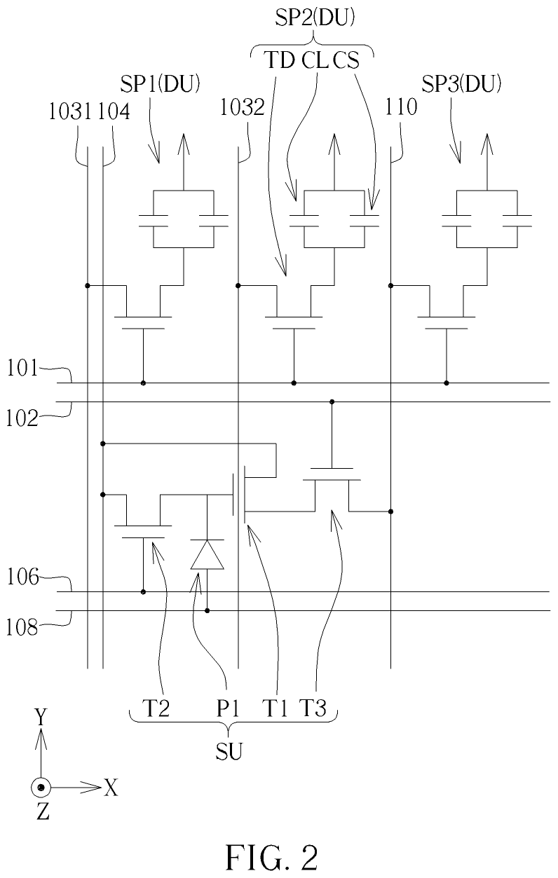

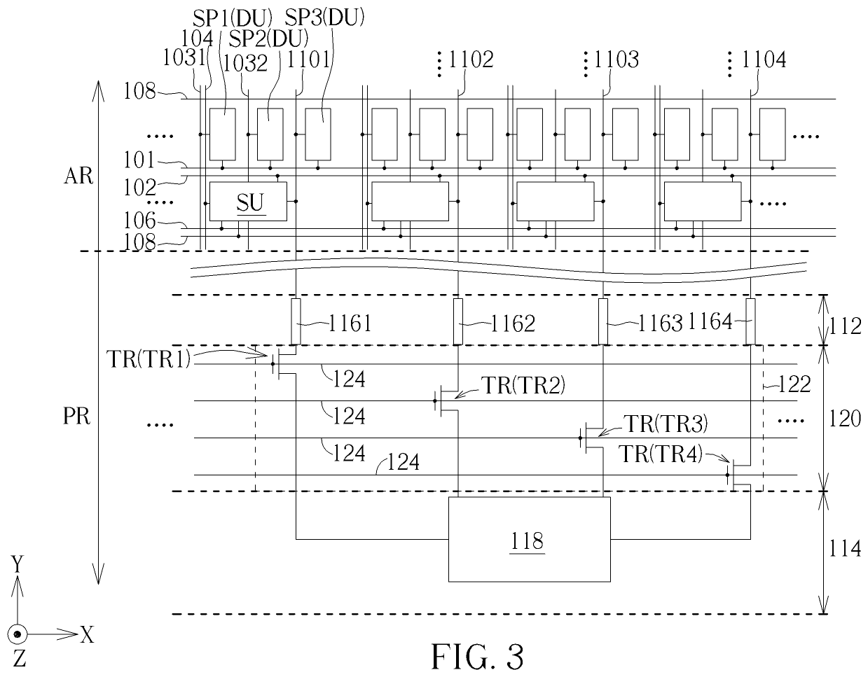

Please refer to FIG. 1 to FIG. 3, FIG. 1 is a schematic diagram of an electronic device according to a first embodiment of the present disclosure, FIG. 2 is a schematic diagram of a sensing unit and display units according to the first embodiment of the present disclosure, and FIG. 3 is a partially enlarged schematic diagram of the electronic device according to the first embodiment of the present disclosure. An electronic device 10 of this embodiment may include the substrate 100, the substrate 100 may include a sensing region AR (also referred to as an active region or a display region) and a non-sensing region PR (also referred to as a peripheral region), and the non-sensing region PR is adjacent to the sensing region AR and can be disposed on at least one side of the sensing region AR. As shown in FIG. 1, the non-sensing region PR may surround the sensing region AR. The sensing region AR may provide the display function, light emitting function, detecting function and/or sensing function, but not limited thereto.

A material of the substrate 100 may include glass, quartz, sapphire, polymer (such as polyimide (PI) or polyethylene terephthalate, (PET)) and/or other suitable materials to be used as a flexible substrate or a rigid substrate, but not limited thereto. Additionally, a shape of a top view of the substrate 100 is not limited to a rectangular shape, and the substrate 100 may have any suitable shape.

The electronic device 10 may include a plurality of sensing units SU, a plurality of display units DU and a plurality of signal lines disposed on the substrate 100, but not limited thereto. The sensing units SU and the display units DU may be disposed in the sensing region AR. In some embodiments, as shown in FIG. 1, the display units DU may be disposed along the direction X, the sensing units SU may also be disposed along the direction X, and the sensing units SU and the display units DU may be alternately disposed in the direction Y, but not limited thereto.

The signal lines may be disposed in the sensing region AR and/or the non-sensing region PR. The signal lines may include a plurality of signal lines 102 (such as but not limited to switch signal lines), a plurality of power lines 104, a plurality of signal lines 106 (such as but not limited to reset signal lines), a plurality of signal lines 108 (such as but not limited to bias voltage lines), a plurality of signal lines 110 (such as but not limited to read out lines), a plurality of scan lines 101, a plurality of data lines 1031, a plurality of data lines 1032 or other signal lines. In some embodiments (as shown in FIG. 1 to FIG. 7), the signal lines 110 may also be used as data lines, but not limited thereto.

The signal lines 102, the scan lines 101, the signal lines 106 and the signal lines 108 may be extended in the direction X, and the power lines 104, the signal lines 110, the data lines 1031 and the data lines 1032 may be extended in the direction Y, but not limited thereto. The signal lines 102, the signal lines 106, the signal lines 108 and the scan lines 101 may cross the power lines 104, the signal lines 110, the data lines 1031 and the data lines 1032, but not limited thereto.

As shown in FIG. 2, in some embodiments, the sensing units SU may be optical sensors for example, and each of the sensing units SU may include a sensing element P1, a thin film transistor T1, a thin film transistor T2 and a thin film transistor T3, but not limited thereto. The sensing element P1 may include a photodiode, a PIN diode or other suitable photoelectric conversion elements, but not limited thereto.

The sensing element P1 may include a first end and a second end, the first end may be one of the P terminal or N terminal, and the second end may be the other one of the P terminal or N terminal. The first end of the sensing element P1 may be electrically connected to the signal line 108. In some embodiments, the signal line 108 may provide a bias voltage so that the sensing element P1 can be operated under a negative bias. The second end of the sensing element P1 may be electrically connected to a gate of the thin film transistor T1 and a second end of the thin film transistor T2.

The gate of the thin film transistor T1 may be electrically connected to the second end of the sensing element P1 and the second end of the thin film transistor T2. A first end of the thin film transistor T1 may be electrically connected to the power line 104. For example, the power line 104 may provide a VDD voltage to the thin film transistor T1, but not limited thereto. A second end of the thin film transistor T1 may be electrically connected to a first end of the thin film transistor T3. The thin film transistor T1 may be used as an amplification transistor to amplify the signal sensed by the sensing element P1, but not limited thereto. In addition, the first end and the second end of the thin film transistor mentioned in this disclosure may be, for example, a source and a drain or a drain and a source.

A gate of the thin film transistor T2 may be electrically connected to the signal line 106. For example, the signal line 106 may provide a reset signal to the thin film transistor T2. A first end of the thin film transistor T2 may be electrically connected to the power line 104. For example, the power line 104 may provide the VDD voltage to the thin film transistor T2, but not limited thereto. The second end of the thin film transistor T2 may be electrically connected to the second end of the sensing element P1 and the gate of the thin film transistor T1. The thin film transistor T2 may be used as a reset transistor and reset the sensing unit SU after the end of the sensing period or before the start of the sensing period.

A gate of the thin film transistor T3 may be electrically connected to the signal line 102, a first end of the thin film transistor T3 may be electrically connected to the second end of the thin film transistor T1, and a second end of the thin film transistor T3 may be electrically connected to the signal line 110. The thin film transistor T3 may be used as a reading transistor, and the thin film transistor T3 or the sensing unit SU can be controlled to output a sensing signal to the signal line 110 by the switch signal of the signal line 102.

In some embodiments, the sensing units SU may be used as fingerprint sensors, iris sensors, retina sensors, face sensors, vein sensors, motion sensors, gesture sensors or other suitable sensors or a combination of at least two of the above, but not limited thereto. In other embodiments, the sensing units SU may include touch sensing functions, but not limited thereto. In other embodiments, the sensing units SU may also include capacitance sensors, ultrasonic sensors, infrared (IR) sensors or other suitable types of sensors.

In some embodiments, each of the display units DU may for example be a sub-pixel, but not limited thereto. As shown in FIG. 2, the display units DU may be liquid crystal display units for example. Each of the display units DU may include a thin film transistor TD, a capacitor CL and a capacitor CS, but not limited thereto. A gate of the thin film transistor TD may be electrically connected to the scan line 101, a first end of the thin film transistor TD may be electrically connected to the data line 1031, the data line 1032 or the signal line 110, and a second end of the thin film transistor TD may be electrically connected to the capacitor CL and the capacitor CS. The capacitor CL may for example be a liquid crystal capacitor, and the capacitor CS may for example be a storage capacitor, but not limited thereto.

The display units DU of the present disclosure are not limited to the liquid crystal display units, and the display units DU may also include other types of display units. For example, when the electronic device 10 is a self-luminous display device, the display unit DU may include at least the data line 1031, the scan line 101, two transistors, a capacitor and a light emitting unit, but not limited thereto. The light emitting unit may for example include an organic light emitting diode (OLED), a quantum light emitting diode (QLED or QDLED), an inorganic light emitting diode (LED), any other suitable light emitting element or a combination of the above. The inorganic light emitting diode may for example include mini LED or micro LED, but not limited thereto.

As shown in FIG. 2, the display units DU may include a sub-pixel SP1, a sub-pixel SP2 and a sub-pixel SP3. The sub-pixel SP1 may be a red sub-pixel, the sub-pixel SP2 may be a green sub-pixel, and the sub-pixel SP3 may be a blue sub-pixel, but not limited thereto. The first end of the thin film transistor TD of the sub-pixel SP1 may be electrically connected to the data line 1031, the first end of the thin film transistor TD of the sub-pixel SP2 may be electrically connected to the data line 1032, and the first end of the thin film transistor TD of the sub-pixel SP3 may be electrically connected to the signal line 110, but not limited thereto. Therefore, in some embodiments, the signal lines 110 may also be used as the data lines to transmit grayscale signals, thereby reducing the number of the signal lines and increasing the aperture ratio, but not limited thereto.

As shown in FIG. 1, the non-sensing region PR of the substrate 100 may include a pad region 112 and a pad region 114, the pad region 112 and the pad region 114 may be disposed on one side of the sensing region AR in the direction Y, and the pad region 112 may be disposed between the pad region 114 and the sensing region AR in the direction Y, but not limited thereto. The electronic device 10 may include a plurality of pads 116 (or may be referred to as the first pads) and a plurality of test pads 118 disposed on the substrate 100. The pads 116 may be disposed in the pad region 112, and the pads 116 may be arranged in at least one row along the direction X. The test pads 118 may be disposed in the pad region 114, and the test pads 118 may be arranged in at least one row along the direction X. The pads 116 and the test pads 118 may be disposed on a same side of the sensing region AR.

The signal lines 110 may be extended from the sensing region AR to the non-sensing region PR. As shown in FIG. 3, one of the signal lines 110 may be electrically connected to the corresponding one of the pads 116, and therefore the sensing units SU may be electrically connected to the pads 116. In some embodiments, the first ends of the thin film transistors TD of the sub-pixels SP3 may be electrically connected to the signal lines 110, and therefore at least a portion of the display units DU (such as the sub-pixels SP3) may be electrically connected to the pads 116, but not limited thereto. For example, as shown in FIG. 3, one of the sub-pixels SP3 and one of the sensing units SU may be electrically connected to one of the signal lines 110 (such as the signal line 1101, the signal line 1102, the signal line 1103 or the signal line 1104).

As shown in FIG. 1 and FIG. 3, the non-sensing region PR of the substrate 100 may include a multiplexer region 120, and the multiplexer region 120 may be disposed between the pad region 112 and the pad region 114 in the direction Y, but not limited thereto. The electronic device 10 may include a plurality of multiplexers 122 (or may be referred to as the first multiplexers) disposed on the substrate 100. The structure of one of the multiplexers 122 is shown in FIG. 3. The multiplexers 122 may be disposed in the multiplexer region 120 in FIG. 1, and the multiplexers 122 may be connected between the pads 116 and the test pads 118.

As shown in FIG. 3, one of the multiplexers 122 may include a plurality of thin film transistors TR and a plurality of signal lines 124. In some embodiments, the thin film transistors TR of the multiplexers 122 may be arranged in four transistor rows, each of the transistor rows may be extended in the direction X, and the gates of the thin film transistors TR in each of the transistor rows may be electrically connected to one of the signal lines 124 (such as the switch signal line).

For example, a signal line 1101 may be electrically connected to a pad 1161, and the pad 1161 may be electrically connected to the thin film transistor TR in a transistor row TR1. A signal line 1102 may be electrically connected to a pad 1162, and the pad 1162 may be electrically connected to the thin film transistor TR in a transistor row TR2. A signal line 1103 may be electrically connected to a pad 1163, and the pad 1163 may be electrically connected to the thin film transistor TR in a transistor row TR3. A signal line 1104 may be electrically connected to a pad 1164, and the pad 1164 may be electrically connected to the thin film transistor TR in a transistor row TR4. In some embodiments, the signal lines 1101, 1102, 1103, and 1104 may for example output the sensing signals of the sensing units SU.

The signal line 1101 to the signal line 1104 and the pad 1161 to the pad 1164 may be electrically connected to one of the test pads 118 through thin film transistors TR in different transistor rows, and one of the test pads 118 may be electrically connected to four signal lines, thereby reducing the number of the signal lines or saving the space occupied by the signal lines. In other words, four pads (such as the pad 1161 to the pad 1164) may be electrically connected to one of the test pads 118 through the thin film transistors TR in four transistor rows (such as the transistor row TR1 to the transistor row TR4).

In addition, the pad 1161 to the pad 1164 may be connected between the test pad 118 and the sensing units SU, and the test pad 118 may be electrically connected to the sensing units SU. Furthermore, the number of the pads 116 may be greater than the number of the test pads 118.

In some embodiments, the thin film transistors TR in different transistor rows can be turned on by transmitting switch signals through different signal lines 124, and the test signals can be transmitted to the corresponding sensing units SU through the pads 116, thus the function of the sensing units SU can be checked through the test pads 118. More specifically, the pads 116 may be electrically connected to a driving unit 126, the driving unit 126 may provide test signals to the corresponding sensing units SU, and the test pads 118 may receive the test signals to determine whether the function of the sensing units SU is normal.

In some embodiments, the sensing units SU can be tested through the test pads 118 after the fabrication of the array substrate of the electronic device 10 is finished, or the sensing units SU can be tested through the test pads 118 after two substrates of electronic device 10 are adhered and the liquid crystal is filled. In this way, the unqualified products can be detected and the overall qualification rate of the electronic device 10 can be improved.

As shown in FIG. 1, the electronic device 10 may include the driving unit 126 disposed on the substrate 100 and in the non-sensing region PR. The driving unit 126 may for example include an integrated circuit chip, but not limited thereto. The driving unit 126 may be electrically connected to the pads 116, and the driving unit 126 may be electrically connected to the sensing units SU and display units DU (such as the sub-pixels SP3) through the pads 116 and the signal lines 110. For example, the driving unit 126 may perform fingerprint identification based on the signals from the sensing units SU, or the driving unit 126 may transmit the grayscale signals to the sub-pixels SP3, but not limited thereto.

In some embodiments, the driving unit 126 may be disposed on the substrate 100 by a die bonding method. In some embodiments, the driving unit 126 may be electrically connected to the pads (such as the pads 116) on the substrate 100 through a flexible printed circuit (FPC). In some embodiments, the driving unit 126 may be fabricated on a flexible film (i.e., chip on film (COF)) and electrically connected to the pads on the substrate 100.

In addition, in the embodiments of the present disclosure, the data lines (such as the data lines 1031, 1032, and 1033) may be extended from the sensing region AR to the non-sensing region PR, and the pads used for electrically connecting the data lines may be disposed in the pad region 112. These pads may also be electrically connected to the driving unit 126, and the driving unit 126 may transmit the grayscale signals to the display units DU (such as the sub-pixels SP1, the sub-pixels SP2 and the sub-pixels SP3), but not limited thereto. In addition, in some embodiments, the electronic device 10 may further include a plurality of multiplexers disposed between the sensing region AR and the pad region 112 in the direction Y, and these multiplexers may be connected between the signal lines 110 and the pads 116, but not limited thereto.

The electronic devices of the present disclosure are not limited to the aforementioned embodiment. The following will continue to disclose other embodiments of the present disclosure. However, in order to simplify the description and highlight the differences between the embodiments, the same reference numerals are used to denote the same elements hereinafter, and the repeated portions will not be described again.

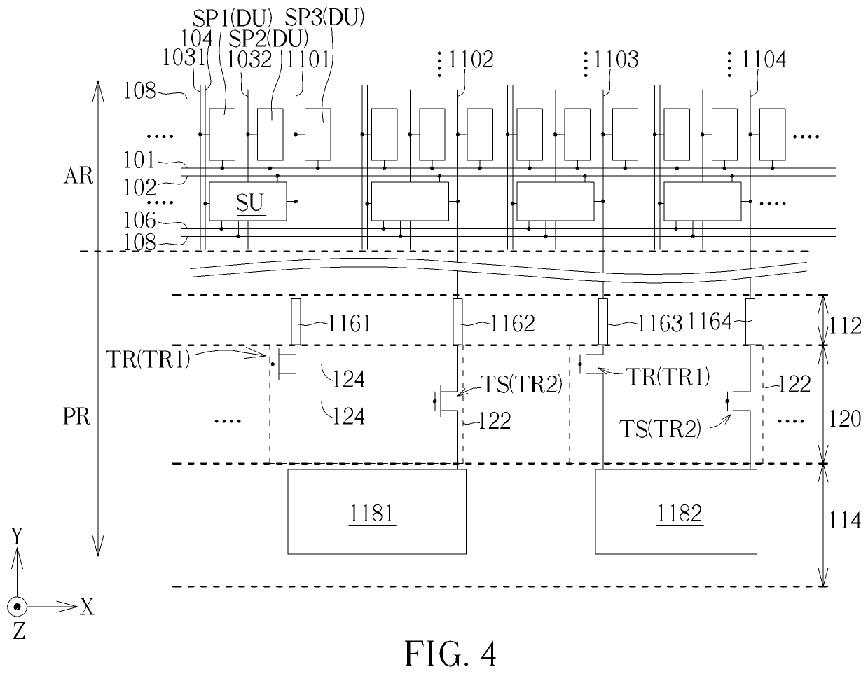

Please refer to FIG. 4, FIG. 4 is a partially enlarged schematic diagram of an electronic device according to a second embodiment of the present disclosure. Different from the first embodiment, the thin film transistors TR and a plurality of thin film transistors TS of the multiplexers 122 may be arranged in two transistor rows in some embodiments.

For example, the signal line 1101 (such as the signal line that can output the sensing signal) may be electrically connected to the pad 1161, and the pad 1161 may be electrically connected to one of the thin film transistors TR in the transistor row TR1. The signal line 1102 may be electrically connected to the pad 1162, and the pad 1162 may be electrically connected to one of the thin film transistors TS in the transistor row TR2. The signal line 1103 may be electrically connected to the pad 1163, and the pad 1163 may be electrically connected to another one of the thin film transistors TR in the transistor row TR1. The signal line 1104 may be electrically connected to the pad 1164, and the pad 1164 may be electrically connected to another one of the thin film transistors TS in the transistor row TR2.

The signal line 1101, the signal line 1102, the pad 1161 and the pad 1162 may be electrically connected to a test pad 1181 through the thin film transistor TR (and/or the thin film transistor TS) in different transistor rows, and therefore the test pad 1181 may be electrically connected to two signal lines. In other words, two pads (such as the pad 1161 and the pad 1162) may be electrically connected to one test pad 1181 through the thin film transistors (such as the thin film transistor TR and the thin film transistor TS) in two transistor rows (such as the transistor row TR1 and the transistor row TR2).

The signal line 1103, the signal line 1104, the pad 1163, and the pad 1164 may be electrically connected to a test pad 1182 through the thin film transistor TS (and/or the thin film transistor TR) in different transistor rows, and therefore the test pad 1182 may be electrically connected to two other read out lines. In addition, the number of the pads 116 may be greater than the number of the test pads 118.

In some embodiments, the thin film transistors TR and the thin film transistors TS in different transistor rows can be turned on by transmitting switch signals through different signal lines 124, and the test signals can be transmitted to the corresponding sensing units SU through the pad 1161 to the pad 1164, thus the test pad 1181 and the test pad 1182 can be used to check whether the function of the sensing units SU is normal.

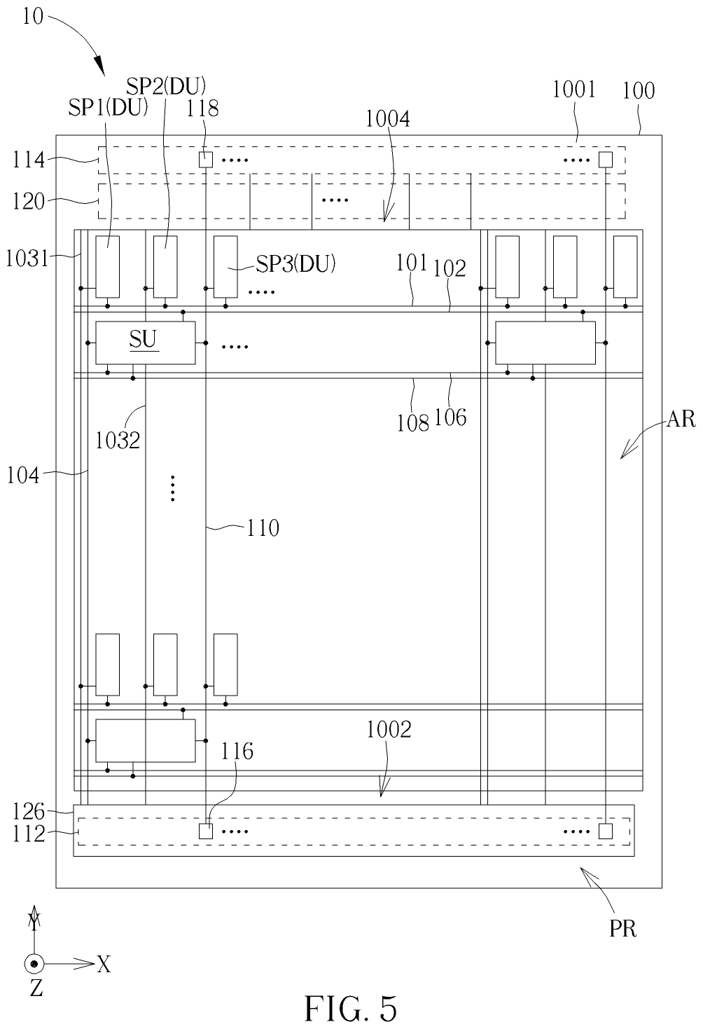

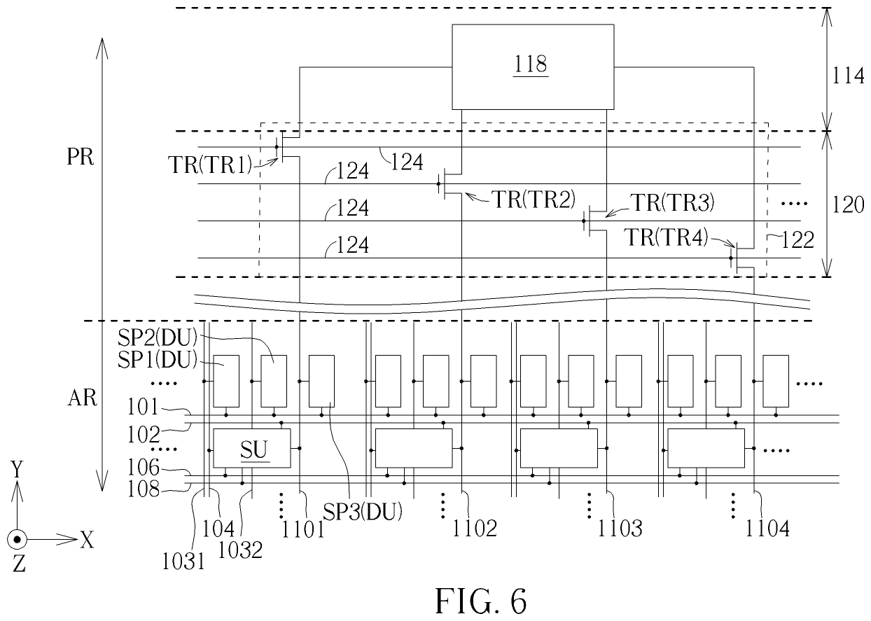

Please refer to FIG. 5 and FIG. 6, FIG. 5 is a schematic diagram of an electronic device according to a third embodiment of the present disclosure, and FIG. 6 is a partially enlarged schematic diagram of the electronic device according to the third embodiment of the present disclosure. In some embodiments, the sensing region AR may include a first side 1002 and a second side 1004, and the first side 1002 may be opposite to the second side 1004 in the direction Y. As shown in FIG. 5, the pad region 112, the pads 116 in the pad region 112 and the driving unit 126 electrically connected to the pads 116 may be disposed on the first side 1002 of the sensing region AR, and the pad region 114, the test pads 118 in the pad region 114 and the multiplexer region 120 (or the multiplexer 122 in FIG. 6) may be disposed on the second side 1004 of the sensing region AR, but not limited thereto.

In some embodiments, as shown in FIG. 5 and FIG. 6, the multiplexer region 120 may be disposed between the pad region 114 and the sensing region AR in the direction Y, and the multiplexers 122 (or may be referred to as the second multiplexers) may be disposed and connected between the sensing units SU and the test pads 118. As shown in FIG. 6, the thin film transistors TR of the multiplexers 122 may be arranged in four transistor rows.

For example, the signal line 1101 may be electrically connected to the thin film transistor TR in the transistor row TR1. The signal line 1102 may be electrically connected to the thin film transistor TR in the transistor row TR2. The signal line 1103 may be electrically connected to the thin film transistor TR in the transistor row TR3. The signal line 1104 may be electrically connected to the thin film transistor TR in the transistor row TR4. In other words, in some embodiments, the signal lines 110 may be electrically connected to the thin film transistors TR in the multiplexers 122 without using the pads 116. In addition, the signal line 1101 to the signal line 1104 may be electrically connected to a test pad 118 through the thin film transistors TR in different transistor rows, and therefore one of the test pads 118 may be electrically connected to four signal lines.

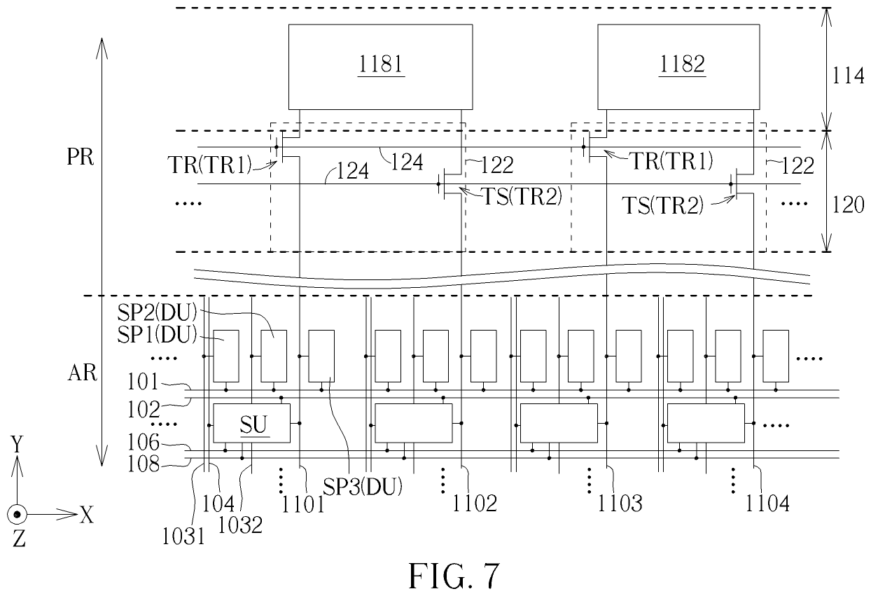

Refer to FIG. 7, FIG. 7 is a partially enlarged schematic diagram of an electronic device according to a fourth embodiment of the present disclosure. Different from the third embodiment, the thin film transistors TR and the thin film transistors TS of the multiplexers 122 may be arranged in two transistor rows in some embodiments. For example, the signal line 1101 may be electrically connected to one of the thin film transistors TR in the transistor row TR1. The signal line 1102 may be electrically connected to one of the thin film transistors TS in the transistor row TR2. The signal line 1103 may be electrically connected to another one of the thin film transistors TR in the transistor row TR1. The signal line 1104 may be electrically connected to another one of the thin film transistors TS in the transistor row TR2. In other words, the signal lines 110 may be electrically connected to the thin film transistors TR and the thin film transistors TS in the multiplexers 122 without using the pads 116 in some embodiments.

In addition, the signal line 1101 and the signal line 1102 may be electrically connected to the test pad 1181 through the thin film transistor TR and the thin film transistor TS in different transistor rows, and therefore the test pad 1181 may be electrically connected to two signal lines. The signal line 1103 and the signal line 1104 may be electrically connected to the test pad 1182 through the thin film transistor TR and the thin film transistor TS in different transistor rows, and therefore the test pad 1182 may be electrically connected to the other two signal lines.

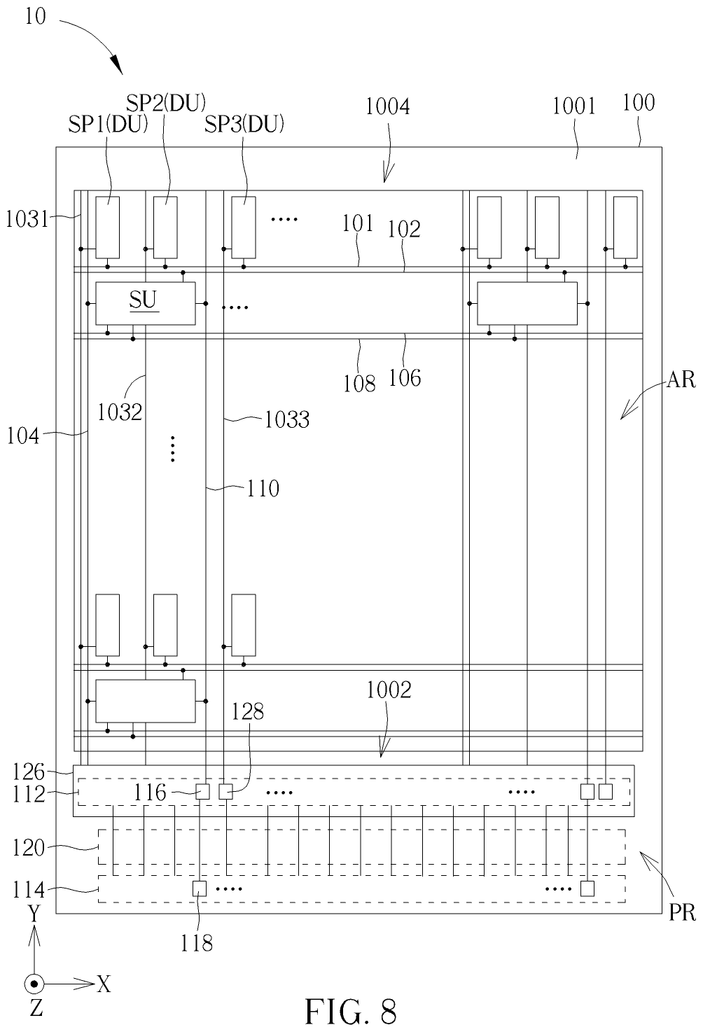

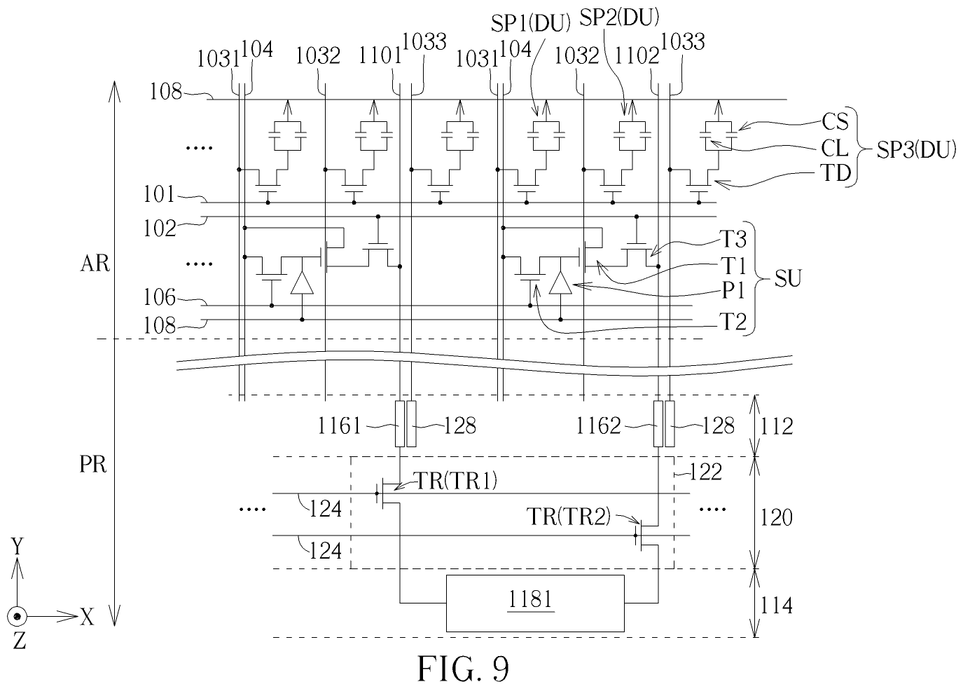

Please refer to FIG. 8 and FIG. 9, FIG. 8 is a schematic diagram of an electronic device according to a fifth embodiment of the present disclosure, and FIG. 9 is a partially enlarged schematic diagram of the electronic device according to the fifth embodiment of the present disclosure. Different from the first embodiment, in some embodiments, a portion of the display units DU (such as the sub-pixels SP3) may not be electrically connected to the signal lines 110, but not limited thereto. As shown in FIG. 8 and FIG. 9, the electronic device 10 may include a plurality of data lines 1033 (or may be referred to as the first conductive lines) and the plurality of signal lines 110 (or may be referred to as the second conductive lines) disposed on the substrate 100, and the data lines 1033 and the signal lines 110 may be extended along the direction Y, but not limited thereto.

As shown in FIG. 9, the second ends of the thin film transistors T3 of the sensing units SU may be electrically connected to the signal lines 110 (such as the signal line 1101 and the signal line 1102), and the first ends of the thin film transistors TD of the display units DU (such as the sub-pixels SP3) may be electrically connected to the data lines 1033, but not limited thereto.

The electronic device 10 may include a plurality of pads 128 (or may be referred to as the second pads) disposed on the substrate 100. The pads 128 and the pads 116 may be disposed in the pad region 112, and the pads 128 and the pads 116 (such as the pad 1161 and the pad 1162) may be arranged in at least one row along the direction X, but not limited thereto.

The data lines 1033 and the signal lines 110 may be extended from the sensing region AR to the non-sensing region PR. As shown in FIG. 8 and FIG. 9, one of the data lines 1033 may be electrically connected to the corresponding one of the pads 128, the data lines 1033 may be connected between the display units DU (such as the sub-pixels SP3) and the pads 128, and therefore the pads 128 may be electrically connected to the display units DU (such as the sub-pixels SP3).

As shown in FIG. 8, one of the signal lines 110 may be electrically connected to the corresponding one of the pads 116, the signal lines 110 may be connected between the sensing units SU and the pads 116, and therefore the pads 116 may be electrically connected to the sensing units SU.

As shown in FIG. 9, the signal line 1101 may be electrically connected to the pad 1161, and the pad 1161 may be electrically connected to the thin film transistor TR in the transistor row TR1. The signal line 1102 may be electrically connected to the pad 1162, and the pad 1162 may be electrically connected to the thin film transistor TR in the transistor row TR2. The signal line 1101, the signal line 1102, the pad 1161 and the pad 1162 may be electrically connected to one of the test pads 118 (or the test pad 1181) through thin film transistors TR in different transistor rows, and therefore one of the test pads 118 (or the test pad 1181) may be electrically connected to two signal lines. Although FIG. 9 illustrates a two-to-one multiplexer 122 as an example, but it is not limited to this. A four-to-one multiplexer 122 (as shown in FIG. 3) may also be used.

In addition, as shown in FIG. 8, the driving unit 126 may be electrically connected to the pads 116 and the pads 128, the driving unit 126 may be electrically connected to the sensing units SU through the pads 116 and the signal lines 110, and the driving unit 126 may be electrically connected to a portion of the display units DU (such as the sub-pixels SP3) through the pads 128 and the data lines 1033. For example, the driving unit 126 may perform fingerprint identification based on the signals from the sensing units SU, and the driving unit 126 may transmit the grayscale signals to the sub-pixels SP3 through the data lines 1033, but not limited thereto.

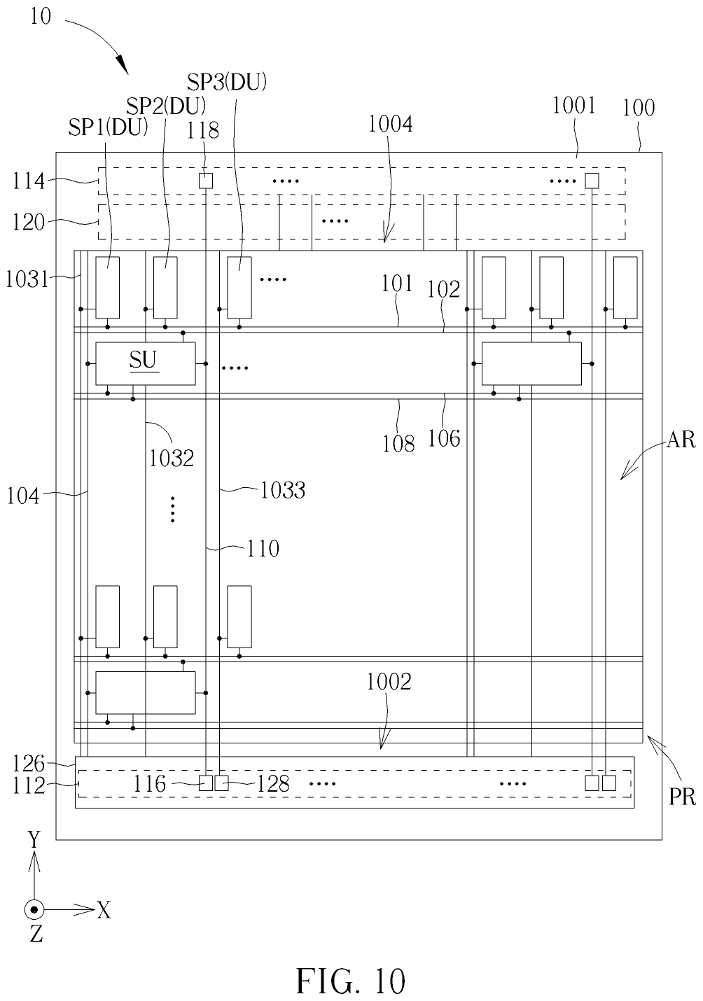

Please refer to FIG. 10, FIG. 10 is a schematic diagram of an electronic device according to a sixth embodiment of the present disclosure. Different from the fifth embodiment, in some embodiments, the pad region 112, the pads 116 and the pads 128 in the pad region 112, and the driving unit 126 electrically connected to the pads 116 and the pads 128 may be disposed on the first side 1002 of the sensing region AR, and the pad region 114, the test pads 118 in the pad region 114, the multiplexer region 120, and the multiplexer 122 in the multiplexer region 120 may be disposed on the second side 1004 of the sensing region AR, but not limited thereto. Similar to FIG. 6, the signal lines 110 may be electrically connected to the thin film transistors TR in the multiplexer 122 without using the pads 116. The connection of the multiplexer 122, the test pads 118 and the signal lines 110 may be referred to FIG. 6, FIG. 7 and/or FIG. 9, and it is not redundantly described herein.

In summary, in the electronic device of the present disclosure, the sensor units and display units can be integrated into the sensing region, the test pads electrically connected to the sensing units can be disposed in the non-sensing region, the test signals can be transmitted to the corresponding sensing units through the first pads, and the function of the sensing units can be checked through the test pads. In addition, the test pads can be electrically connected to the signal lines through the multiplexer, thereby reducing the number of the signal lines or saving the space occupied by the signal lines.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a plurality of first pads disposed on the substrate;
a plurality of sensing units disposed on the substrate and electrically connected to the plurality of first pads; and
a plurality of test pads disposed on the substrate and electrically connected to the plurality of sensing units.

2. The electronic device according to claim 1, wherein the plurality of first pads are connected between the plurality of test pads and the plurality of sensing units.

3. The electronic device according to claim 2, further comprising a plurality of first multiplexers connected between the plurality of first pads and the plurality of test pads.

4. The electronic device according to claim 3, wherein a number of the plurality of first pads is greater than a number of the plurality of test pads.

5. The electronic device according to claim 3, wherein in one of the plurality of first multiplexers, four of the plurality of first pads are electrically connected to one of the plurality of test pads.

6. The electronic device according to claim 5, wherein the one of the plurality of first multiplexers comprises a plurality of thin film transistors arranged in four transistor rows, and the four of the plurality of first pads are electrically connected to the one of the plurality of test pads through the plurality of thin film transistors in the four transistor rows.

7. The electronic device according to claim 3, wherein in one of the plurality of first multiplexers, two of the plurality of first pads are electrically connected to one of the plurality of test pads.

8. The electronic device according to claim 7, wherein the one of the plurality of first multiples comprises a plurality of thin film transistors arranged in two transistor rows, and the two of the plurality of first pads are electrically connected to the one of the plurality of test pads through the plurality of thin film transistors in the two transistor rows.

9. The electronic device according to claim 1, further comprising a plurality of second multiplexers connected between the plurality of sensing units and the plurality of test pads.

10. The electronic device according to claim 1, further comprising a plurality of display units and a plurality of second pads disposed on the substrate, and the plurality of second pads are electrically connected to the plurality of display units.

11. The electronic device according to claim 10, further comprising a plurality of first conductive lines and a plurality of second conductive lines, wherein the plurality of first conductive lines are connected between the plurality of display units and the plurality of second pads, and the plurality of second conductive lines are connected between the plurality of sensing units and the plurality of first pads.

12. The electronic device according to claim 10, further comprising a driving unit electrically connected to the plurality of first pads and the plurality of second pads.

13. The electronic device according to claim 10, wherein the plurality of second pads and the plurality of first pads are arranged in at least one row.

14. The electronic device according to claim 1, further comprising a plurality of display units disposed on the substrate, wherein the plurality of display units are electrically connected to the plurality of first pads.

15. The electronic device according to claim 14, further comprising a plurality of conductive lines connected between the plurality of sensing units and the plurality of first pads, and one of the plurality of sensing units and one of the plurality of display units are electrically connected to one of the conductive lines.

16. The electronic device according to claim 1, wherein the substrate comprises a sensing region and a non-sensing region adjacent to the sensing region, and the plurality of first pads and the plurality of test pads are disposed in the non-sensing region.

17. The electronic device according to claim 16, further comprising a plurality of display units disposed on the substrate, and the plurality of display units and the plurality of sensing units are disposed in the sensing region.

18. The electronic device according to in claim 16, wherein the plurality of first pads and the plurality of test pads are disposed on a same side of the sensing region.

19. The electronic device according to claim 16, wherein the plurality of first pads are disposed on a first side of the sensing region, and the plurality of test pads are disposed on a second side of the sensing region, and the first side is opposite to the second side.

20. The electronic device according to claim 16, further comprising a driving unit disposed in the non-sensing region, wherein the driving unit is connected to the plurality of first pads.
